(19) United States
(12) Patent Application Publication
(10) Pub. No.: US 2019/0096962 A1
(43) Pub. Date: Mar. 28, 2019

(54) PIXEL STRUCTURE FOR ORGANIC LIGHT-EMITTING DIODES, DISPLAY PANEL AND DISPLAY DEVICE INCLUDING THE SAME

(71) Applicant: Shanghai Tianma AM-OLED Co., Ltd., Shanghai (CN)

(72) Inventors: Lijing HAN, Shanghai (CN); Lu LIU, Shanghai (CN); Xian CHEN, Shanghai (CN)

(21) Appl. No.: 15/882,152

(22) Filed: Jan. 29, 2018

(30) Foreign Application Priority Data
Sep. 28, 2017 (CN) 201710896026.2

(51) Int. Cl. H01L 27/32; H01L 51/00; H01L 51/56

(52) U.S. Cl. CPC H01L 27/3218; H01L 51/5012; H01L 51/56; H01L 51/0011

(57) ABSTRACT

The present invention provides a pixel structure for organic light-emitting diodes, including three types of pixel groups arranged in array. Each of the three types of pixel groups includes two adjacent sub-pixels having a same color. The sub-pixels in pixel groups of different types have different colors. Any two of the pixel groups of the same type are neither adjacent to each other in the row direction nor adjacent to each other in the column direction. The two sub-pixels of each pixel groups in a same row are both arranged in a first direction or both arranged in a second direction, an included angle between the first direction and the row direction is α, 0°≤α≤90°, and the second direction is perpendicular to the first direction. The present design can achieve a compact arrangement of sub-pixels, improve the pixel density and increases the aperture ratio.

### CROSS-REFERENCE TO RELATED APPLICATIONS

The present application claims priority to Chinese Patent Application No. 201710896026.2, filed on Sep. 28, 2017, the content of which is incorporated herein by reference in its entirety.

### TECHNICAL FIELD

The present invention relates to the technical field of display technologies and, in particularly, relates to a pixel structure for organic light-emitting diodes, a display panel having the organic light-emitting diode and a display device having the organic light-emitting diode.

### BACKGROUND

Organic light-emitting diode (OLED) is becoming a new generation of display technology due to its advantages of self-luminous, wide viewing angle, high contrast ratio, low power consumption and short response time.

Generally, the organic light-emitting display device includes a plurality of pixel units, each of which includes a red pixel, a green pixel and a blue pixel. A color display of the organic light-emitting display device can be achieved through a color combination of the red pixel, green pixel and blue pixel. During the production of an organic light-emitting display device, the red pixels, green pixels and blue pixels are generally formed by vapor deposition. Generally, a fine metal mask (FMM) is cooperatively used in the process of the vapor deposition. However, the precision of the production of the fine metal mask and capability of the vapor deposition process both affect the production of the organic light-emitting layer, thereby limiting the arrangement of the pixels.

In the related art, in most cases, the red pixels, and the green pixels and the blue pixels are all strip-shaped pixels and are arranged sequentially by being parallel to one another. Due to the precision of the production of the fine metal mask and the capability of vapor deposition process, the interval between the adjacent pixels is relatively large, so that a high pixel density is difficult to achieve. Pixel density refers to the number of pixels per inch (PPI), and the strip-shaped pixels result in a lower aperture ratio of the pixel structure. On the basis of the related art, in order to increase the pixel density of an organic light-emitting display device, the organic light-emitting display device often adopts an algorithm to realize the display function. That is, each pixel unit includes two pixels having different colors, and a color combination of this pixel unit is achieved by “borrowing” a pixel having a third color from an adjacent pixel unit. The pixel density herein should be understood as the density of the pixel units. Although the adoption of algorithm can increase the density of the pixel units in the organic light-emitting display device to a certain extent, the arrangement of the pixels constituting the pixel unit is not changed, and the pixel density remains unchanged. That is, the influence resulted from the precision of the production of the fine metal mask and capability of the vapor deposition process is not fundamentally mitigated or eliminated. Therefore, the contribution of the algorithm to improving the resolution of the organic light-emitting display device is limited.

Since the requirement on the resolution of a display device is increasing, an urgent problem to be solved is how to fundamentally improve the resolution of the organic light-emitting display device.

### SUMMARY

The present invention provides a pixel structure for organic light-emitting diodes, a display panel having the organic light-emitting diode and a display device having the organic light-emitting diode, for improving the resolution of an organic light-emitting display device.

In a first aspect, the present invention provides a pixel structure for organic light-emitting diodes, including three types of pixel groups arranged in an array, i.e., first pixel groups, second pixel groups and third pixel groups;

each pixel group of each of the three types of pixel groups includes two adjacent sub-pixels having a same color, i.e., a first sub-pixel and a second sub-pixel, the sub-pixels in pixel groups of different types have different colors;

any two of the pixel groups of the same type are neither adjacent in the row direction of the array nor in the column direction of the array;

the two sub-pixels of each pixel groups in a same row are arranged in a first direction or the two sub-pixels of each of the pixel groups in a same row are arranged in a second direction, and the second direction is perpendicular to the first direction;

wherein an angle α between the first direction and the row direction is 0°≤α≤90°.

In a second aspect, the present invention provides a display panel, including the organic light-emitting diode according to the present invention.

In a third aspect, the present invention provides a display device, including the display panel according to the present invention.

Compared with the related art, the organic light-emitting diode, the display panel and the display device according to the present invention have the following beneficial effects:

In the pixel structure for organic light-emitting diodes according to the present invention, in a first aspect, each of the pixel groups of three types includes two adjacent sub-pixels having the same color, thereby reducing the risk of color mixing of three types of pixel groups during the vapor deposition, and the reduced interval between sub-pixels achieve a compact arrangement of the sub-pixels, thereby improving the resolution. In a second aspect, any two of pixel groups of the same type are neither adjacent to each other in the row direction nor adjacent to each other in the column direction, so that the sub-pixels having different colors are uniformly distributed and thus the appearance of bright lines and bright edges formed by sub-pixels of the same color is avoided. In a third aspect, the two sub-pixels of a pixel group are arranged in a first direction or a second direction, and an included angle is present between the first direction and the row direction, so that the arrangement of the sub-pixels in the row direction and the column direction tends to be balanced, facilitating the shapes of the sub-pixels to be uniformly distributed in the row direction and the column direction and improving the aperture ratio of the pixel structure. In the meantime, a compact arrangement of the sub-pixels is achieved, which increases the sub-pixel density and thus improves the resolution of the display device.

### BRIEF DESCRIPTION OF DRAWINGS

FIG. 1 illustrates a cross-sectional view of an organic light-emitting display panel in the related art;

FIG. 2 illustrates a schematic diagram of a pixel structure for organic light-emitting diodes in the related art;

FIG. 3 illustrates a structural schematic diagram of a fine metal mask, corresponding to the pixel structure for organic light-emitting diodes shown in FIG. 2;

FIG. 4 illustrates a schematic diagram of a pixel structure for organic light-emitting diodes in the related art, the pixel structure adopting an algorithm.

FIG. 5 illustrates a schematic diagram of a pixel structure for organic light-emitting diodes provided in an embodiment of the present invention;

FIG. 6 illustrates a schematic diagram of another pixel structure for organic light-emitting diodes provided in an embodiment of the present invention;

FIG. 7 illustrates a schematic diagram of another pixel structure for organic light-emitting diodes provided in an embodiment of the present invention;

FIG. 8 illustrates a schematic diagram of another pixel structure for organic light-emitting diodes provided in an embodiment of the present invention;

FIG. 9 illustrates a partial schematic diagram of the pixel structure for organic light-emitting diodes shown in FIG. 5;

FIG. 10 illustrates a schematic diagram of another pixel structure for organic light-emitting diodes provided in an embodiment of the present invention;

FIG. 11 illustrates a structural schematic diagram of a fine metal mask, corresponding to the pixel structure for organic light-emitting diodes shown in FIG. 6;

FIG. 12 illustrates a schematic diagram of another pixel structure for organic light-emitting diodes provided in an embodiment of the present invention;

FIG. 13 illustrates a partial schematic diagram of the pixel structure for organic light-emitting diodes shown in FIG. 12;

FIG. 14 illustrates a schematic diagram of another pixel structure for organic light-emitting diodes provided in an embodiment of the present invention;

FIG. 15 illustrates a partial schematic diagram of the pixel structure for organic light-emitting diodes shown in FIG. 14;

FIG. 16 illustrates a partial schematic diagram of the pixel structure for organic light-emitting diodes shown in FIG. 12;

FIG. 17 illustrates a schematic diagram of another pixel structure for organic light-emitting diodes provided in an embodiment of the present invention;

FIG. 18 illustrates a schematic diagram of another pixel structure for organic light-emitting diodes provided in an embodiment of the present invention;

FIG. 19 illustrates a schematic cross-sectional structure of a pixel group provided in an embodiment of the present invention;

FIG. 20 illustrates a display panel provided in an embodiment of the present invention; and

FIG. 21 illustrates a display device provided in an embodiment of the present invention.

### DESCRIPTION OF EMBODIMENTS

The present invention will be further described in detail as follows in specific embodiments with reference to the accompanying drawings. It should be understood that, these embodiments are only used to explain the present invention, but not intended to limit the scope of the present invention.

FIG. 1 illustrates a schematic cross-sectional view of an organic light-emitting display panel in the related art. As shown in FIG. 1, the organic light-emitting display panel generally includes an array substrate 1 and an organic light-emitting functional layer 2. The organic light-emitting functional layer 2 includes a plurality of organic light-emitting elements 3 separated by a pixel definition layer PDL. The pixel definition layer PDL includes a plurality of apertures, in which the organic light-emitting elements 3 are located. The organic light-emitting elements 3 can include an anode 31, an organic light-emitting layer 32 and a cathode 33 which are sequentially arranged. The organic light-emitting element 3, according to the material thereof, can correspondently emit red, green or blue light by applying different potentials to the anode 31 and the cathode 33 of the organic light-emitting element 3. In addition, the array substrate 1 of the organic light-emitting display panel includes a plurality of thin-film transistors 4, the plurality of thin-film transistors 4 form a pixel circuit for driving the organic light-emitting element 3 to emit light. It can be understood that, in order to protect the organic light-emitting element from the erosion of water and oxygen from the external environment, the organic light-emitting display panel generally further includes an upper substrate. The structure and material of the upper substrate can be different in different types of organic light-emitting display panels. For example, in a rigid organic light-emitting display panel, the upper substrate can be an encapsulation cover plate made of glass, and in a flexible organic light-emitting display panel, the upper substrate can be a thin-film encapsulation layer, and the film encapsulation layer can be formed by laminated inorganic and organic layers.

In the related art, the organic light-emitting layer 32 in the organic light-emitting element 3 is generally formed by the vapor deposition process, and a fine metal mask is required in the vapor deposition process. Specifically, a substrate to be vapor deposited is placed in a vapor deposition chamber, a vapor deposition material passes through the openings on the fine metal mask placed on a side of the substrate to be deposited with an organic light-emitting layer, and then forms the organic light-emitting layer on the substrate. The organic light-emitting layers corresponding to the red pixels, the green pixels and the blue pixels are respectively formed in different vapor deposition processes. Since the pattern of the organic light-emitting layer formed through the openings of the fine metal mask is generally larger than the corresponding openings in the vapor deposition process, i.e., a problem of vapor deposition diffusion at the edges of the openings may occur. Therefore, in order to prevent the organic light-emitting layer corresponding to pixels of a certain color from extending to a position where the adjacent organic light-emitting layer corresponding to pixels of another color is located, i.e., a color mixing phenomenon can be avoided. On the basis of the capability of the related art, the interval between the adjacent pixels with different colors is limited. On the other hand, in order to meet the user's requirement on high resolution of the display panel, the pixels are arranged more compactly, and the openings of the fine metal mask is becoming much smaller, thereby increasing the production complexity of the fine metal mask. Meanwhile, in order to achieve a good structural property of the fine metal mask and to ensure that no deformation or breakage occurs between adjacent openings, the interval between the openings cannot be too small. The limitation to the interval between the openings may correspondently affect the design of pixel structure on its high-resolution characteristics.

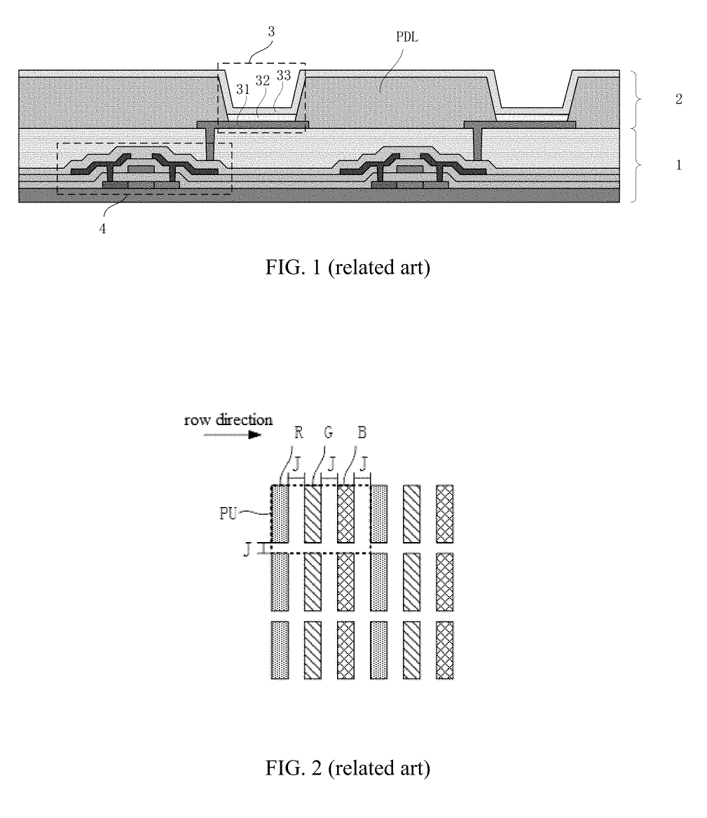

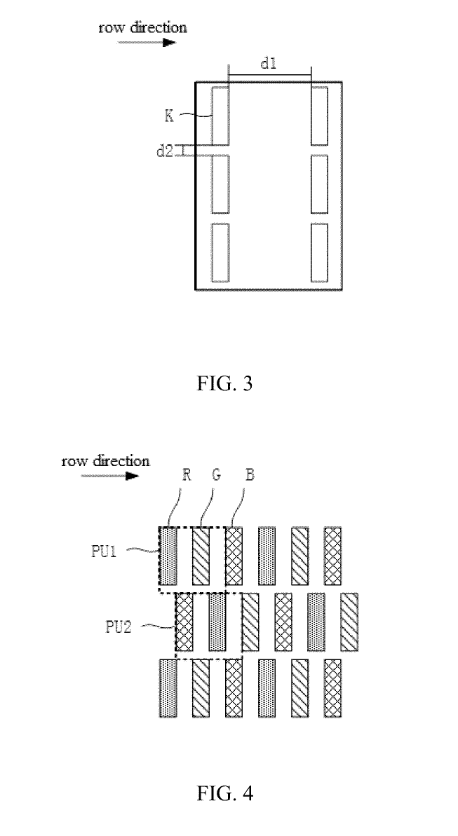

The existing vapor deposition process and the precision and difficulty of the production of the fine metal mask both limit the arrangement of the pixel structure for organic light-emitting diodes. FIG. 2 illustrates a schematic diagram of a pixel structure for organic light-emitting diode in the related art. As shown in FIG. 2, the pixel structure for organic light-emitting diodes includes a plurality of pixels arranged in an array, and red pixels R, green pixels G and blue pixels B are sequentially arranged in a row direction. Every three adjacent red pixel R emitting red light, green pixel G emitting green light and blue pixel B emitting blue light constitute a pixel unit PU, and the color display of the pixel unit PU is achieved by a color combination of the red pixel R, green pixel G and blue pixel B in the pixel unit PU. On the one hand, as shown in FIG. 2, each pixel unit PU has three pixel intervals J in the row direction, and one interval J in a direction perpendicular to the row direction. In order to avoid the color mixing problem of vapor deposition, the interval between the pixels is limited, i.e., the interval between the pixels cannot be too small. Under this limitation, if the shape of the pixel is a square or the length of the pixel in the row direction is greater than that in the direction perpendicular to the row direction, the length of the pixel unit PU in the row direction will be much greater than that in the direction perpendicular to the row direction, which is negative to the color combination of the three pixels in the pixel unit PU and thus may affect the display effect. Therefore, in order to ensure a compact arrangement of three pixels in the pixel unit PU, the pixels are generally strip-shaped pixels and the short sides of the pixels are parallel to the row direction. Specifically, the pixel shape can be changed from a square to a strip as follows: the length of the side of the square parallel to the row direction is reduced by a fixed value, and the length of the side of the square perpendicular to the row direction is increased by the fixed value. It can be seen from the conversion that the area of the converted strip is smaller than that of the original square, i.e., the light-emitting area of the converted strip pixel is smaller than that of the original square pixel, and thus the aperture ratio of the pixel structure is reduced. On the other hand, the openings in the fine metal mask corresponding to the pixels are also made as a strip shape, and the arrangement of the short sides of the strips increases the difficulty of producing the openings.

In addition, the interval difference between the openings in the fine metal mask in different directions also affects the compact arrangement of the pixels. FIG. 3 is a schematic diagram of a fine metal mask corresponding to the pixel structure for organic light-emitting diodes shown in FIG. 2. As shown in FIG. 3, the fine metal mask has a plurality of openings K, and the pattern of openings on the fine metal mask corresponds to the arrangement pattern of the same type of pixels in the pixel structure for organic light-emitting diodes shown in FIG. 2. For example, by the aid of the fine metal mask, the arrangement pattern of the red pixels R in the pixel structure for organic light-emitting diodes shown in FIG. 2 is formed in one vapor deposition process. Since a green pixel G and a blue pixel B is provided between two adjacent red pixels R in the row direction and no pixel of colors other than red color is provided between two adjacent red pixels R in the direction perpendicular to the row direction, the interval d1 between two adjacent openings K in the row direction is much greater than the interval d2 between two adjacent openings K in the direction perpendicular to the row direction. In order to achieve a good structural property of the fine metal mask and to ensure that no deformation or breakage occurs between adjacent openings, the interval between the openings cannot be too small, since the value of interval d2 may correspondently affect the high-resolution arrangement of pixel structure.

In order to improve the resolution, the display function of the pixel structure is achieved by algorithms. FIG. 4 illustrates a schematic diagram of a pixel structure for organic light-emitting diodes in the related art, the pixel structure adopting an algorithm. As shown in FIG. 4, in the pixel structure, every two adjacent pixels having different colors in the row direction constitute a pixel unit (such as the pixel unit PU1 and the pixel unit PU2), and a combination of pixel colors is realized by “borrowing” a pixel having a third color in the adjacent pixel unit, so as to achieve a color display. The expression “borrowing” means that the pixel having the third color emits the luminance required by itself and also the borrowed luminance in the meantime. For example, a first pixel unit PU1 located in a first row is composed of a red pixel R and a green pixel G, and the pixel color combination is achieved by “borrowing” a blue pixel B located in a first pixel unit PU2 of a second row. During display, the luminance emitted by the blue pixel located in the pixel unit PU2 includes, in addition to the required luminance of the blue pixel B in the pixel unit PU2, the luminance of the blue pixel B required in the pixel unit PU1, and the reconfiguration of the luminance of the blue pixel B achieves a rendering effect of the pixels. Although the pixel structure adopting the algorithm shown in FIG. 4 can improve the resolution of a display panel to a certain extend, the specific structure of the pixel arrangement is maintained, that is, the pixel density does not change, and thus the problem that the available vapor deposition process and the precision requirement and difficulty of the production of the fine metal mask all limit the arrangement of the pixel structure for organic light-emitting diodes is not fundamentally alleviated or eliminated. Therefore, the contribution to improving the resolution of the display panel is very limited.

In order to effectively improve the resolution of the organic light-emitting display panel, an embodiment of the present invention provides a pixel structure for organic light-emitting diodes. FIG. 5 illustrates a schematic diagram of a pixel structure for organic light-emitting diodes according to an embodiment of the present invention. As shown in FIG. 5, the pixel structure for organic light-emitting diodes includes three types of pixel groups 5 arranged in an array, i.e., first pixel groups 51, second pixel groups 52 and third pixel groups 53. Each of pixel groups 5 of a specific type includes two adjacent sub-pixels 50 having a same color, i.e., a first sub-pixel 501 and a second sub-pixel 502. That is, the pixel group 5 includes a first sub-pixel 501 and a second sub-pixel 502. These two sub-pixels 50 have a same color, and no other sub-pixel 50 is arranged between these two sub-pixels 50. The sub-pixels 50 in different types of pixel groups 5 have different colors. In one embodiment, the sub-pixels 50 of the first pixel groups 51, second pixel groups 52 and third pixel groups 53 have the color of red, green and blue, respectively.

Referring to FIG. 5, any two of pixel groups 5 of the same type are not adjacent in both the row direction and column direction. For example, one second pixel group 52 and one third pixel group 53 are arranged between every two first pixel groups 51 in the row direction, while one second pixel group 52 and one third pixel group 53 are arranged between every two first pixel groups 51 in the column direction.

Two sub-pixels in each of the pixel groups in the same row are arranged along a first direction or two sub-pixels of each of the pixel groups in a same row are arranged in a second direction.

FIG. 5 illustrates a pixel arrangement structure of four pixel group rows and seven pixel group columns. As shown in FIG. 5, in a first pixel group row 81, a second pixel group row 82, a third pixel group row 83 and a fourth pixel group row 84, the two sub-pixels 50 in each pixel group 5 are arranged in the first direction.

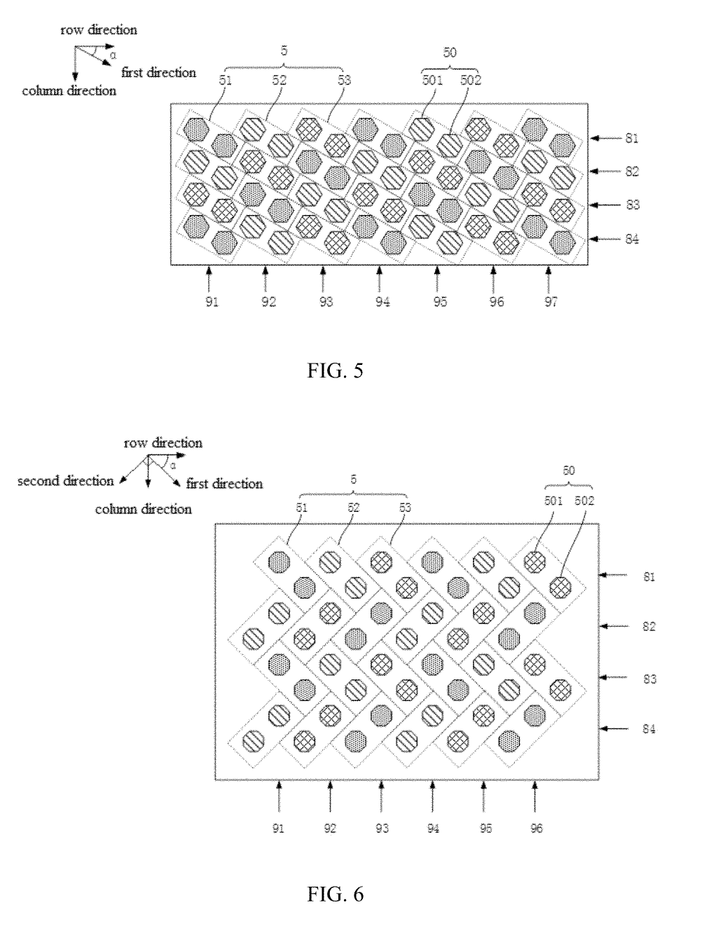

FIG. 6 illustrates a schematic diagram of another pixel structure for organic light-emitting diodes provided in another embodiment. FIG. 6 illustrates a pixel arrangement structure of four pixel group rows and six pixel group columns. In the first pixel group row 81 and the third pixel group row 83, the two sub-pixels 50 in each pixel group 5 are arranged in the first direction, and in the second pixel group row 82 and the fourth pixel group row 84, the two sub-pixels 50 in each pixel group 5 are arranged in the second direction.

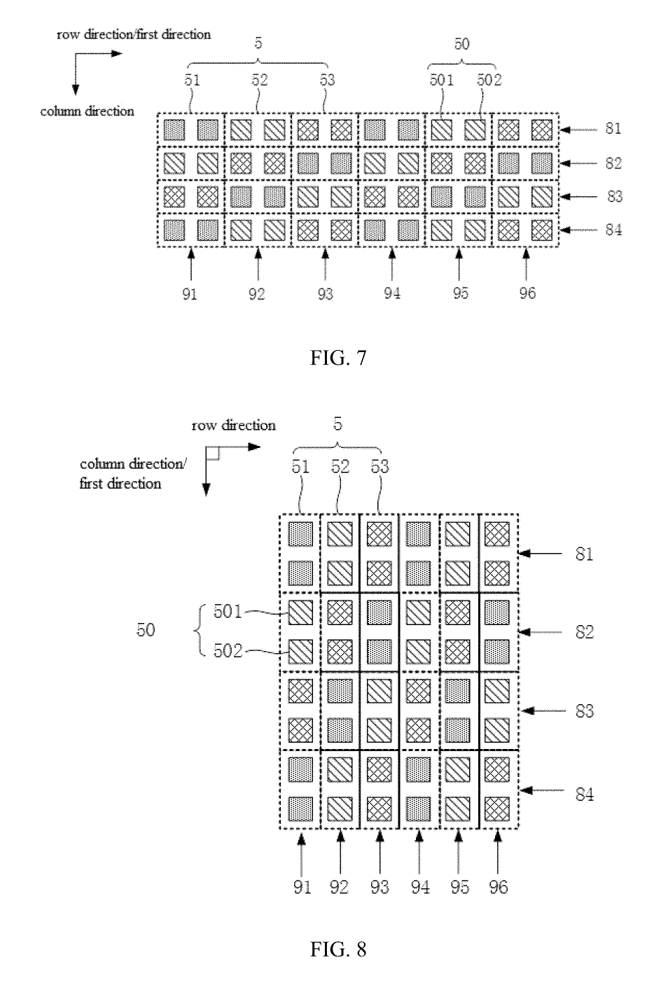

An angle α between the first direction and the row direction is 0°≤α≤90°, and the second direction is perpendicular to the first direction. FIGS. 5-8 respectively show the pixel structure with different values of angle α. In an implementation, as shown in FIG. 5, the value of a can be 30°. In the row direction, the second sub-pixel 502 in one pixel group 5 and the first sub-pixel 501 in an adjacent pixel group 5 are adjacent to one another and different in color, and the colors of these two sub-pixels 50 can be combined to form a pixel unit for realizing color display. In another possible implementation, as shown in FIG. 6, the value of a can be 45°. FIG. 7 illustrates a schematic diagram of another pixel structure for organic light-emitting diodes provided in an embodiment, wherein the value of α can be 0°, i.e., the first direction is parallel to the row direction. FIG. 8 illustrates a schematic diagram of another pixel structure for organic light-emitting diodes provided in an embodiment, wherein the value of α can be 90°, i.e., the first direction is parallel to the column direction. In the column direction, the second sub-pixel 502 in one pixel group 5 and the first sub-pixel 501 in an adjacent pixel group 5 are adjacent to one another and different in color, and the colors of these two sub-pixels 50 can be combined to form a pixel unit for realizing color display.

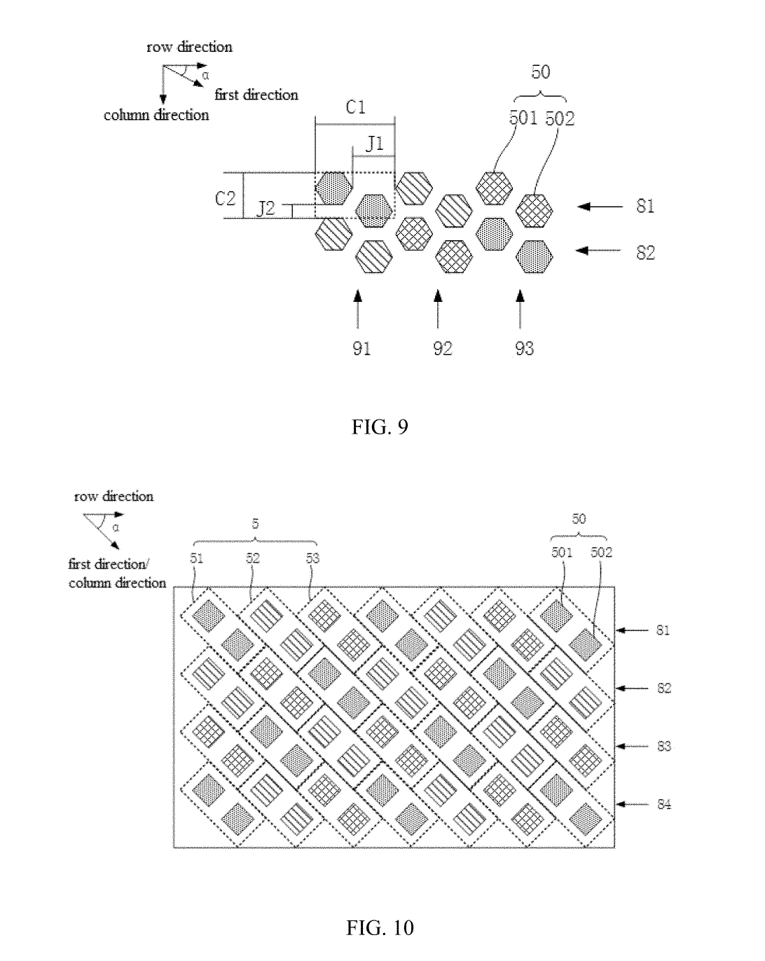

When an angle is formed between the first direction and the row direction, arrangement of sub-pixels in the row direction and the column direction tend to be balanced. FIG. 9 illustrates a partial schematic diagram of the pixel structure for organic light-emitting diodes shown in FIG. 5. As shown in FIG. 9, the pixel structure has a plurality of repeating portions, and the repeating portion is shown by the dashed box in FIG. 9. Each of the repeating portions has a length C1 in the row direction and a length C2 in the column direction. When the sum of the length C1 and the length C2 is a constant, the closer the value of length C1 and that of the length C2 are, the larger the area of the repeating portion is. Therefore, the repeating arrangement portion is generally provided with a square shape, in order to make the repeating portion have a larger area in a limited region. In each of the repeating portions, the sub-pixels 50 have intervals J1 in the row direction and intervals J2 in the column direction. The closer the value of the interval J1 and the interval J2 are, the more uniform the arrangement of sub-pixels 50 in the row direction and in the column direction is. In the meantime, the shapes of the sub-pixels 50 can also be uniformly distributed in the row direction and the column direction. Correspondingly, the area of the sub-pixel is increased, i.e., the aperture ratio of the pixel structure is increased.

With regards to the pixel structure for organic light-emitting diodes provided in the embodiments of the present invention, on the one hand, by providing three different types of pixel groups and each of the pixel groups has two adjacent sub-pixels with the same color, the problem of color mixing between two sub-pixels in the same pixel group can be avoided. Therefore, the two sub-pixels in the same pixel group can correspond to a same opening on the fine metal mask, thereby increasing the opening and lowering the difficulty of the production of the fine metal mask. In the related art, the problem of color mixing may occur between any two adjacent pixels. Compared with the related art, the present design can greatly reduce the possibility of color mixing during the vapor deposition, and reduce the difficulty of the vapor deposition procedure. On the other hand, any two of pixel groups of the same type are not adjacent in the row direction and the column direction, so that the sub-pixels of different colors are uniformly distributed, which facilitates the color combination between sub-pixels of different colors. Meanwhile, the same type of pixel groups (or the sub-pixels of the same type) are avoided from being continuously arranged in a row or in a column, i.e., the phenomenon of bright lines and bright edges formed by sub-pixels of the same color is avoided. In a third aspect, two sub-pixels in a pixel group are arranged along the first direction or the second direction, and an angle is formed between the first direction and the row direction, so that the arrangement of the sub-pixels in the row direction and the column direction tends to be balanced, thereby facilitating the shapes of the sub-pixels to be uniformly distributed in the row direction and the column direction and improving the aperture ratio of the pixel structure; in the meantime, a compact arrangement of the sub-pixels is achieved, which increases the sub-pixel density and thus improves the resolution of the display device.

In an embodiment, in the row direction, the first pixel group, the second pixel group and the third pixel group are sequentially and cyclically arranged. In the row direction, the pixel groups are arranged in pixel group rows. Each pixel group row includes a minimum repeating unit, which can be composed of the first, the second and the third pixel groups arranged sequentially, or can be composed of the second, the third and the first pixel groups arranged sequentially, or can be composed of the third, the first and the second pixel groups arranged sequentially. As shown in FIG. 5, in the first pixel group row 81 and the fourth pixel group row 84, the minimum repeating unit is composed of the first pixel group 51, the second pixel group 52 and the third pixel group 53, and the first pixel group 51, the second pixel group 52 and the third pixel group 53 are arranged sequentially; in the second pixel group row 82, the minimum repeating unit is composed of the second pixel group 52, the third pixel group 53 and the first pixel group 51, and the second pixel group 52, the third pixel group 53, and the first pixel group 51 are arranged sequentially; in the third pixel group row 83, the minimum repeating unit is composed of the third pixel group 53, the first pixel group 51 and the second pixel group 52, and the third pixel group 53, the first pixel group 51 and the second pixel group 52 are arranged sequentially. With this arrangement manner, in the row direction, colors of sub-pixels are uniformly distributed, and sub-pixels in each pixel group can select a sub-pixel in an adjacent pixel group for color combination, thereby achieving the color display. Meanwhile, the bright lines and bright edges formed by continuously arranging the sub-pixels of the same color in one row are avoided, which is advantageous to the uniformity of image display.

In a pixel structure for organic light-emitting diodes provided in an embodiment of the present invention, two sub-pixels of each pixel group in a same pixel group row are all arranged along the first direction. As shown in FIG. 5, FIG. 7, and FIG. 8, in the first pixel group row 81, the second pixel group row 82, the third pixel group row 83 and the fourth pixel group row 84, two sub-pixels 50 of each pixel group 5 are arranged along the first direction.

In an embodiment, the first pixel group, the second pixel group and the third pixel group are sequentially and cyclically arranged in the column direction. In the column direction, the pixel groups are sequentially arranged as a pixel group column, and each pixel group column includes a minimum repeating unit, and the minimum repeating unit can be composed of the first, the second and the third pixel groups arranged sequentially, or can be composed of the second, the third and the first pixel groups arranged sequentially, or can be composed of the third, the first and the second pixel groups arranged sequentially. As shown in FIG. 5, in the first pixel group column 91, the fourth pixel group column 94 and the seventh pixel group column 97, the minimum repeating unit is composed of the first pixel group 51, the second pixel group 52 and the third pixel group 53, and the first pixel group 51, the second pixel group 52 and the third pixel group 53 are arranged sequentially; in the second pixel group column 92 and the fifth pixel group column 95, the minimum repeating unit is composed of the second pixel group 52, the third pixel group 53 and the first pixel group 51, and the second pixel group 52, the third pixel group 53 and the first pixel group 51 are arranged sequentially; in the third pixel group column 93 and the sixth pixel group column 96, the minimum repeating unit is composed of the third pixel group 53, the first pixel group 51 and the second pixel group 52, and the third pixel group 53, the first pixel group 51 and the second pixel group 52 are arranged sequentially. With this arrangement manner, in the column direction, colors of sub-pixels are uniformly distributed, and sub-pixels in each pixel group can select a sub-pixel in an adjacent pixel group for color combination, so that the color display can be achieved. Meanwhile, the bright lines and bright edges formed by continuously arranging the sub-pixels of the same color in one column are avoided, which is advantageous to the uniformity of image display.

In an embodiment, the first pixel group, the second pixel group and the third pixel group are sequentially and cyclically arranged in the column direction. The column direction is the first direction, i.e., the first pixel group, the second pixel group and the third pixel group are sequentially and cyclically arranged in the first direction. The arrangement manner of the first pixel group, the second pixel group and the third pixel group is the same as the above-mentioned arrangement manner, which is not described herein again. FIG. 10 illustrates a schematic diagram of another pixel structure for organic light-emitting diodes provided in another embodiment. As shown in FIG. 10, the first pixel group 51, the second pixel group 52 and the third pixel group 53 are sequentially and cyclically arranged in the first direction, and in the meantime, the two sub-pixels 50 in a pixel group 5 are also along the first direction. In the first direction, the second sub-pixel 502 in a pixel group 5 is adjacent to the first sub-pixel 501 in an adjacent pixel group 5. In such an arrangement, in the first direction, two adjacent pixel groups 5 of the same type are separated by four sub-pixels sequentially arranged in the first direction. For example, in the first direction, two adjacent first pixel groups 51 are separated by the two sub-pixels 50 in the second pixel group 52 and two sub-pixels 50 in the third pixel group 53, these four sub-pixels being sequentially arranged in the first direction. In an embodiment, on the one hand, the pixel colors are uniformly distributed in the first direction, and each of the sub-pixels in the pixel groups can select the sub-pixel in the adjacent pixel groups for color combination, thereby achieving the color display; on the other hand, the interval between two adjacent pixel groups of the same type is relatively large in the first direction, and correspondingly, the interval between the two corresponding openings in the fine metal mask used is relatively large either. In this way, the fine metal mask is endowed with good structural performance, and the openings are not deformed or no breakage occurs between adjacent openings. Therefore, in the case of ensuring the structural performance of the fine metal mask, the interval between pixel groups can be properly reduced, thereby achieving a compact arrangement of sub-pixels and improving the pixel density.

In another pixel structure for organic light-emitting diodes provided in an embodiment of the present invention, two sub-pixels in each of the pixel groups in the odd-numbered rows are arranged in a first direction, and two sub-pixels of each of the pixel groups in the even-numbered rows are arranged in a second direction. As shown in FIG. 6, in the first pixel row and the third pixel row, two sub-pixels 50 in each pixel group 5 are arranged in the first direction, and in the second pixel row and the fourth pixel row, two sub-pixels 50 in each pixel group 5 are arranged in the second direction. In such an arrangement, two sub-pixels in the pixel groups of the adjacent pixel group rows have different directions. Compared with the sub-pixels in each pixel group arranged in the same direction, the visual effect of the linear arrangement can be weakened, thereby achieving a more uniform distribution of the sub-pixel colors.

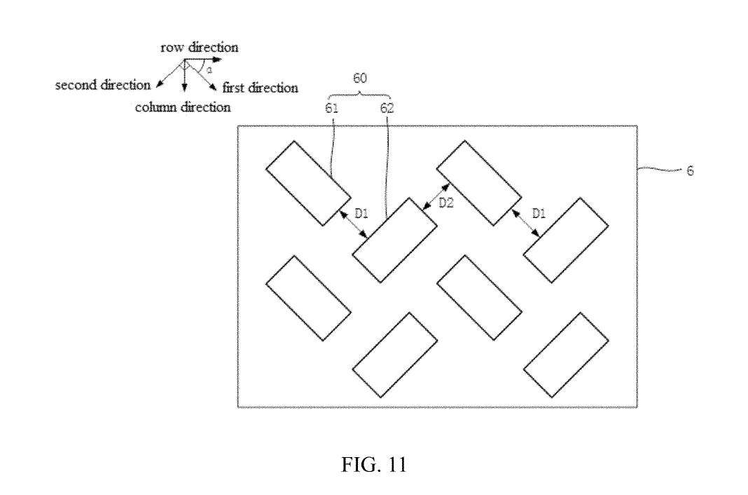

FIG. 11 is a schematic diagram of a fine metal mask, corresponding to the pixel structure for organic light-emitting diodes in FIG. 6. As shown in FIG. 11, the fine metal mask 6 has a plurality of openings 60, the openings 60 are in the form of strip. The opening 60 includes a first opening 61 and a second opening 62, wherein the long side of the first opening 61 is parallel to the first direction and the long side of the second opening 62 is parallel to the second direction. The fine metal mask 6 can be used for the vapor deposition of the pixel structure for organic light-emitting diodes shown in FIG. 6. Specifically, the pattern of the openings 60 in the fine metal mask 6 corresponds to the arrangement pattern of the pixel groups 5 of the same type in the pixel structure shown in FIG. 6. The three arrangement patterns formed by the three types of pixel groups can be respectively formed in three vapor deposition processes using the same fine metal mask, and each of the openings 60 corresponds to a pixel group 5. For example, in a vapor deposition process, the arrangement of the plurality of first pixel groups 51 in the pixel structure for organic light-emitting diodes shown in FIG. 6 can be formed by cooperatively using the fine metal mask 6. The first pixel groups 51 located in the first pixel group row 81 and the third pixel group row 83 are formed through the first openings 61, and the first pixel groups 51 located in the second pixel group row 82 and the fourth pixel group row 84 are formed through the second openings 62, and thus the first opening 61 is adjacent to two second openings 62 of adjacent rows. Specifically, the short side of the first opening 61 is adjacent to the long side of one of the second openings 62, and the interval between the two openings 60 is D1. The long side of the first opening 61 is adjacent to the short side of another second opening 62, and the interval between the two openings 60 is D2. At the same time, the second opening 62 is adjacent to two first openings 61 in adjacent rows. Specifically, the short side of the second opening 62 is adjacent to the long side of one of the first openings 61, the interval between the two openings 60 is D1, while the long side of the second opening 62 is adjacent to the short side of another first opening 61, the interval between the two openings 60 is D2. The first openings and the second openings are in a staggered arrangement. This arrangement is advantageous for balancing the interval from the long sides and the short sides of the opening to the adjacent openings. In this way, the values of D1 and D2 tend to be relatively close or equal to one another, so that the openings have the same structural properties on both the long side and the short side. Compared with the related art, in the case of ensuring the structural performance of the fine metal mask, this arrangement is beneficial to realize the compact arrangement of pixel groups (or sub-pixels) and achieve high-density pixel arrangement.

In an embodiment, in a column of pixel groups, the pixel groups in the odd-numbered rows are the same type of pixel groups, the pixel groups in the even-numbered rows are the same type of pixel groups, and the type of the pixel groups located in the odd-numbered rows are different from the type of the pixel groups located in the even-numbered rows. As shown in FIG. 6, in the first pixel group column 91, the pixel groups 5 located in the first pixel group row 81 and the third pixel group row 83 are the first pixel group 51; the pixel groups 5 located in the second pixel group row 82 and the four pixel group rows 84 are the second pixel groups 52. In the column direction, the pixel groups of the same type are arranged with interval, so that the sub-pixels having the same color are prevented from being continuously arranged in a column and thus forming bright lines or bright edges, thereby achieving the uniformity of the image display.

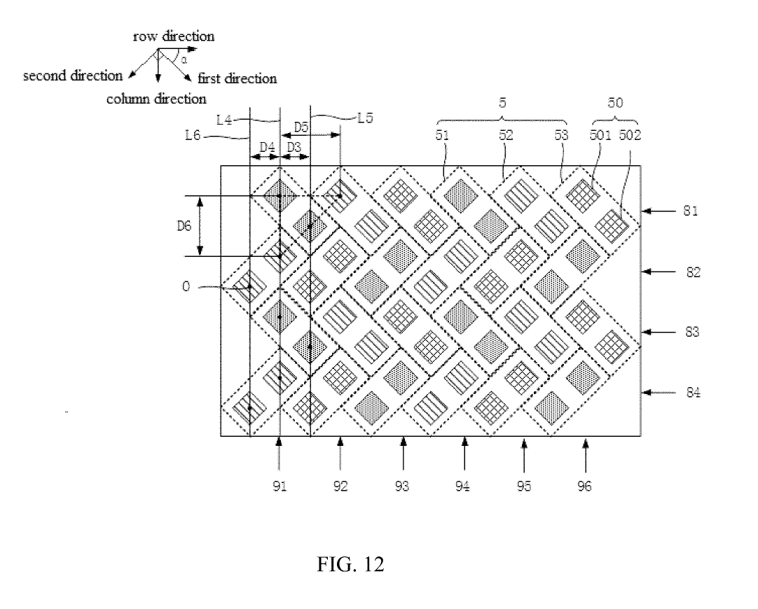

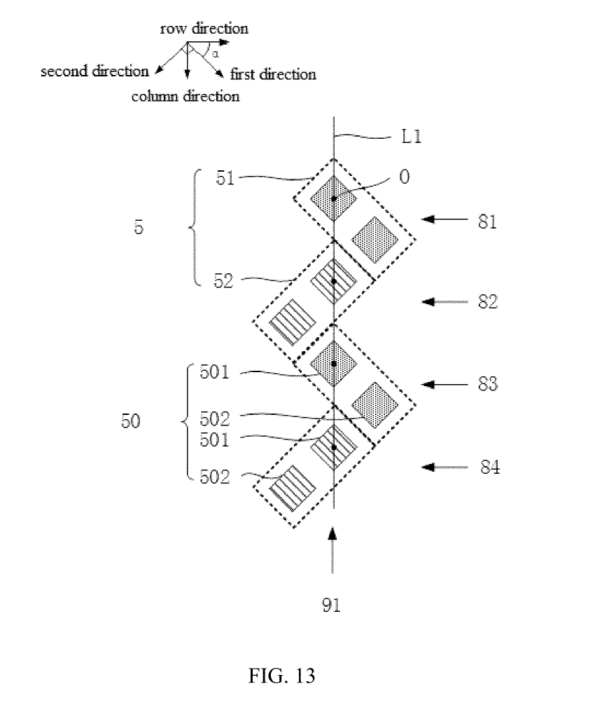

In an embodiment, in the same column of pixel groups, the pixel groups in the odd-numbered rows and the pixel groups in the even-numbered rows are in a staggered arrangement; in the column direction, geometric centers of each first sub-pixels are located on a same straight line, the second sub-pixels of the pixel groups in each odd-numbered rows are located on one side of the straight line, and the second sub-pixels of the pixel groups in each even-numbered rows are located on the other side of the straight line. FIG. 12 illustrates a schematic diagram of another pixel structure for organic light-emitting diodes provided in an embodiment of the present invention. As shown in FIG. 12, in the pixel groups 5 of the odd-numbered rows, the two sub-pixels 50 in each pixel group 5 are arranged in a first direction, and in the pixel groups 5 of the even-numbered rows, the two sub-pixels 50 in each pixel group 5 are arranged in a second direction. FIG. 13 is a partial schematic diagram of the pixel structure for organic light-emitting diodes shown in FIG. 12. Specifically, FIG. 13 illustrates a first pixel group column 91 shown in FIG. 12. In the first pixel group column 91, the pixel groups 5 in the odd-numbered rows (e.g., the first pixel group row 81, the third pixel group row 83) and the pixel groups 5 in the even-numbered rows (e.g., the second pixel group row 82, the fourth pixel group row 84) are in a staggered arrangement. Specifically, in the column direction, the geometric centers O of the first sub-pixels 501 of each pixel group 5 in the first pixel group column 91 are located on a same straight line L1, and the second sub-pixels 502 of the pixel groups 5 in the first pixel group row 81 and the third pixel group row 83 are located on the right side of the straight line L1, and the second sub-pixels 502 of the pixel groups 5 in the second pixel group row 82 and the fourth pixel group row 84 are all located on the left side of the straight line L1. In this arrangement, adjacent pixel groups can be closely arranged in the column direction in such a way that the adjacent pixel groups can have overlapping portions in the row direction.

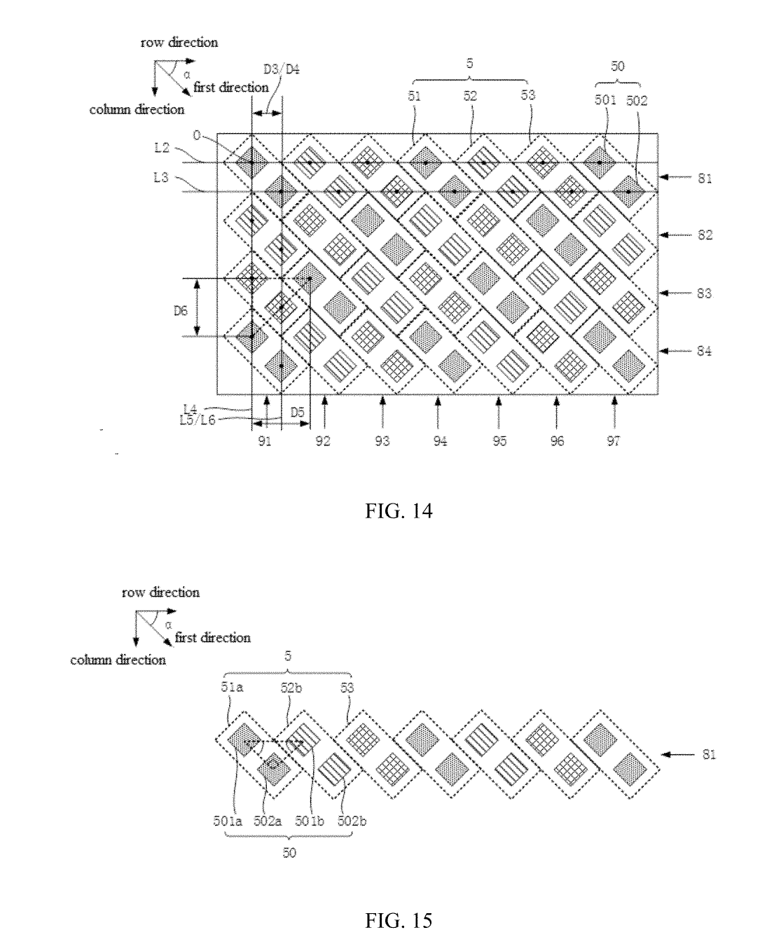

On the basis of the organic light-emitting diode provided in the embodiments described above, in the same pixel group row, the geometric centers of the first sub-pixels are located on a same straight line in the row direction and the first sub-pixels are uniformly arranged, while the geometrical centers of the second sub-pixels are located on a same straight line and the second sub-pixels are uniformly arranged. FIG. 14 is a schematic diagram of another pixel structure for organic light-emitting diodes provided in an embodiment of the present invention. As shown in FIG. 14, in the pixel groups of the same row, such as the first pixel group row 81, the geometric centers O of each of the first sub-pixels 501 are located on a same straight line L2 in the row direction, and the first sub-pixels 501 are arranged uniformly, i.e., the intervals between two geometric centers of the adjacent first sub-pixels 501 are the same or the interval between two adjacent first sub-pixels 501 are the same. In the following description, the expression “uniformly arranged” can be explained in the same way. At the same time, the geometric centers O of each of the second sub-pixels 502 are located on the same straight line L3, and second sub-pixels 502 are uniformly arranged so that the first sub-pixels and the second sub-pixels are arranged orderly.

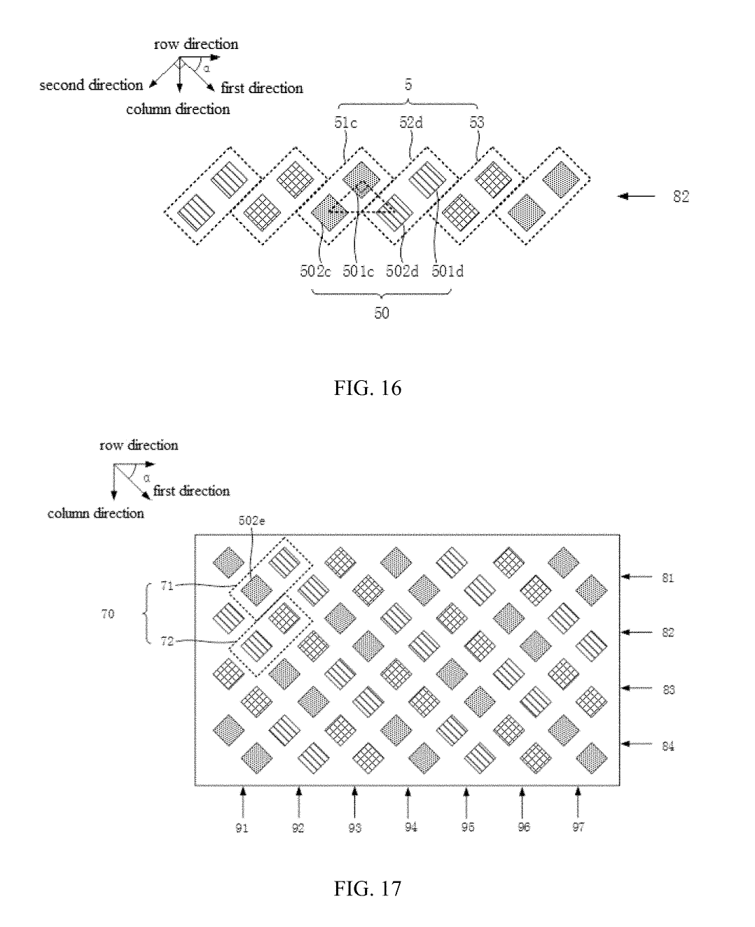

In an embodiment, the angle formed between the first direction and the row direction is 45°. In the pixel groups of the same row, the arrangement direction of the two adjacent sub-pixels of two adjacent pixel groups is perpendicular to that of two sub-pixels in a pixel group. FIG. 15 is a partial schematic diagram of the pixel structure for organic light-emitting diodes shown in FIG. 14. Specifically, FIG. 15 illustrates the first pixel group row 81 of the pixel structure for organic light-emitting diodes shown in FIG. 14. Referring to FIGS. 14 and 15, in the pixel groups of the same row, the two sub-pixels 50 of each pixel group 5 are arranged in the first direction, and the two adjacent sub-pixels 50 in two adjacent pixel groups 5 are arranged in a direction perpendicular to the first direction. For example, the pixel group 51a is adjacent to the pixel group 52b, the pixel group 51a includes a first sub-pixel 501a and a second sub-pixel 502a, the pixel group 52b includes a first sub-pixel 501b and a second sub-pixel 502b, the arrangement direction of the two adjacent sub-pixels 502a and 501b is perpendicular to the first direction. In this design, the geometric centers of the two sub-pixels in the pixel group 51a and the sub-pixel 501b form three vertexes of an isosceles right triangle, and the interval between the sub-pixel 502a and the sub-pixel 501a is equal to the interval between the sub-pixel 502a and the sub-pixel 501b. The color of the sub-pixel 502a is different from that of the sub-pixel 501b. When the colors of the sub-pixel 502a and the sub-pixel 501b are combined for color display, the interval between the sub-pixel 502a and the sub-pixel 501b can be smaller, thereby achieving the compact arrangement of sub-pixels and increasing the pixel density. In another implementation, FIG. 16 illustrates a partial schematic diagram of the pixel structure for organic light-emitting diodes shown in FIG. 12, and specifically illustrates the second pixel group row 82 of the pixel structure for organic light-emitting diodes shown in FIG. 12. In this pixel group row, two sub-pixels 50 in each pixel group 5 are arranged in a second direction and two adjacent sub-pixels 50 in two adjacent pixel groups 5 are arranged in a direction perpendicular to the second direction. For example, the pixel group 51c is adjacent to the pixel group 52d, the pixel group 51c includes a first sub-pixel 501c and a second sub-pixel 502c, the pixel group 52d includes a first sub-pixel 501d and a second sub-pixel 502d, the arrangement direction of the two adjacent sub-pixels 501c and 502d is perpendicular to the second direction. This design can bring the same effects described above, which are not repeated herein.

In an embodiment, in the pixel groups of the same column, the geometric centers of each first sub-pixels are located on the same straight line and the first sub-pixels are uniformly arranged, the geometric centers of each second sub-pixels of the pixel groups in the odd-numbered rows are located on the same straight line and the second sub-pixels are arranged uniformly and the geometric centers of each second sub-pixels of the pixel groups in the even-numbered rows are located on the same straight line and the second sub-pixels are arranged uniformly. Meanwhile, a first interval is present between the straight line corresponding to the second sub-pixels of the pixel groups in the odd-numbered rows and the straight line corresponding to the first sub-pixels, a second interval is present between the line corresponding to the second sub-pixels of the pixel groups in the even-numbered rows and the straight line corresponding to the first sub-pixels, and the first interval is equal to the second interval.

In an implementation, as shown in FIG. 14, in the pixel groups of the same column, such as the first pixel group column 91, the geometric centers O of each of the first sub-pixels 501 are located on a same straight line L4, and the first sub-pixels 501 are uniformly arranged. The geometric centers O of each of the second sub-pixels 502 in the first pixel group row 81 and the third pixel group row 83 are located on a same straight line L5, and the second sub-pixels 502 are uniformly arranged. The geometric centers O of each of the second sub-pixels 502 in the second pixel group row 82 and the fourth pixel group row 84 are located on a same straight line L6, and the second sub-pixels 502 are uniformly arranged. The first interval D3 is present between the straight line L5 corresponding to the second sub-pixels 502 of the pixel groups in the odd-numbered row and the straight line L4 corresponding to the first sub-pixels 501, and the second interval D4 is present between the line L6 corresponding to the second sub-pixels 502 of the pixel groups in the even-numbered row and the straight line L4 corresponding to the first sub-pixels 501, and the first interval D3 is equal to the second interval D4. As shown in FIG. 14, the straight line L5 and the straight line L6 overlap with one another, i.e., the second sub-pixels 502 of the pixel groups in the odd-numbered row and the odd-numbered row are arranged on the same straight line.

In another implementation as shown in FIG. 12, which is different from the relationship between the straight line L5 and the straight line L6 shown in FIG. 14, in the pixel groups of the same column, the straight line L5 and the straight line L6 are respectively located on the two sides of the straight line L4.

In one embodiment, referring to FIG. 12 and FIG. 14, the column direction is perpendicular to the row direction, and in the pixel groups of the same row, a third interval D5 is present between the geometric centers O of two adjacent first sub-pixels 501; in the pixel groups of the same column, a fourth interval D6 is present between the geometric centers O of two adjacent first sub-pixels 501, and the third interval D5 is equal to the fourth interval D6. As shown in FIG. 12 with dashed triangle, the length of a side of the triangle in the row direction corresponds to the value of the third interval D5, the length of a side of the triangle in the column direction corresponds to the value of the fourth interval D6. Since the row direction is perpendicular to the column direction and the third interval D5 is equal to the fourth interval D6, the triangle is an isosceles right triangle. According to the above description, the geometric centers of the three sub-pixels are located on the hypotenuse of the triangle. In this arrangement, the plurality of sub-pixels are arranged not only along the same straight line in the first direction but also along the same straight line in the second direction and, at the same time, the arrangement density of sub-pixels along the row direction is the same as that along the column direction, thereby improving the overall uniformity of sub-pixels in the pixel structure.

In one embodiment, the angle α is in a range of 30°<α<60°. Through limiting the angle α within the range of 30°<α<60°, the arrangement of sub-pixels in the row direction and the column direction tend to be more uniform, and thus the compact arrangement and aperture ratio of the pixel structure are realized. In the meantime, it is advantageous for the sub-pixels in a pixel group to facilitate the color combination with the adjacent sub-pixels in the same row direction and the color combination with the adjacent sub-pixels in the same column direction.

FIG. 17 is a schematic diagram of another pixel structure for organic light-emitting diodes provided in an embodiment of the present invention. As shown in FIG. 14 and FIG. 17, in one implementation, the display can be achieved by pixel rendering. The pixel structure for organic light-emitting diodes can include a plurality of pixel units 70. One pixel unit 70 includes two adjacent sub-pixels 50 having different colors. During display, sub-pixels 50 located in one pixel unit 70 can provide two or more pixel units 70 with luminance, and the pixel rendering effect is achieved by the luminance distribution. For example, the pixel unit 71 is adjacent to the pixel unit 72, and the luminance of the sub-pixel 502e in the pixel unit 71 can be allocated to both the pixel unit 71 and the pixel unit 72, so that both the pixel unit 71 and the pixel unit 72 have the luminance provided by the sub-pixel 502e, thereby achieving the effect of pixel rendering. FIG. 17 schematically illustrates one of the manners for dividing the pixel units. Those skilled in the art can divide the pixel units according to the arrangement principle of the sub-pixels and actual requirements, which is not limited in the present invention.

As regards the organic light-emitting diode described above, the display function can be achieved by adopting an algorithm. The specific steps of the algorithm are as follows: firstly, the theoretical data signal values respectively corresponding to the two sub-pixels in the pixel unit are obtained from the display information data; secondly, using the preset pixel display algorithm, the actual data signal values respectively corresponding to two sub-pixels in the pixel unit are calculated; finally, the actual data signal values are respectively input to the two sub-pixels of the pixel unit for image display.

In the step of calculating the actual data signal values respectively corresponding to the two sub-pixels in the pixel unit by adopting the preset pixel display algorithm, the actual data signal value of the sub-pixel is a weighted sum of the theoretical data signal value of the sub-pixel and the desired theoretical data signal values in adjacent pixel units utilizing this sub-pixel. It should be understood that the actual data signal value of the sub-pixel which is not utilized by other pixel units is equal to the theoretical data signal value of the sub-pixel.

The sub-pixel is in a shape of square, and the two opposite sides of the square are parallel to the first direction, while the other two opposite sides are perpendicular to the first direction. As shown in FIG. 12 and FIG. 14, the shape of the sub-pixel 50 is a square, so that the shape of the sub-pixel has the same length in the row direction and the column direction, i.e., the shape is uniformly distributed, thereby increasing the area of the sub-pixel. Meanwhile, two of the opposite sides of the square are parallel to the first direction, while the other two opposite sides are perpendicular to the first direction and can be matched with the arrangement direction of the sub-pixels, so that both the interval between two sub-pixels in the same pixel group and the interval between two adjacent pixel groups can be advantageously reduced.

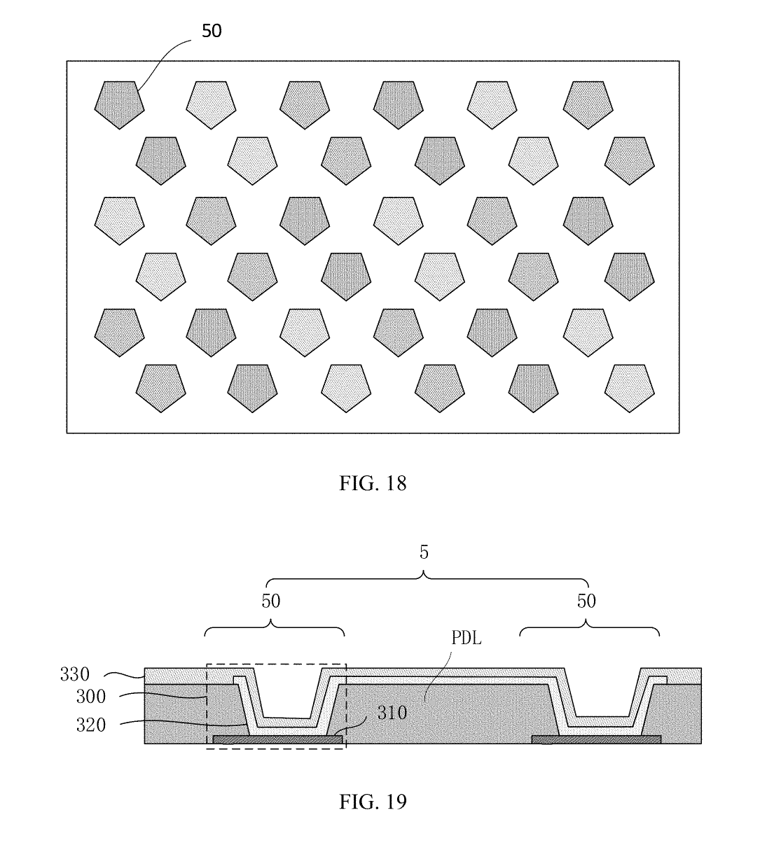

In an embodiment, the sub-pixel can be in shape of regular pentagon, regular hexagon or regular octagon. As shown in FIG. 5, the shape of the sub-pixel is a hexagon. As shown in FIG. 6, the shape of the sub-pixel is an octagon. FIG. 18 illustrates another pixel structure for organic light-emitting diodes provided in an embodiment of the present invention. As shown in FIG. 18, the shape of the sub-pixel 50 is a regular pentagon. The regular polygon shape of the sub-pixel is beneficial to ensure that the shape of the sub-pixel has the same length in the row direction and the column direction, which facilitates the balanced distribution in the row direction and the column direction and increases the opening area of the sub-pixels.

When two sub-pixels share a same opening on the fine metal mask, the pixel structure has corresponding features. FIG. 19 illustrates a schematic cross-sectional structure of a pixel group provided in an embodiment of the present invention. As shown in FIG. 19, the sub-pixel 50 includes an organic light-emitting element 300. The organic light-emitting element 300 includes an anode 310, an organic light-emitting layer 320 and a cathode 330 arranged sequentially. The organic light-emitting layers 320 of two sub-pixels 50 in the pixel group 5 are connected as an integral structure.

It should be understood that, in order to ensure uniform size of the openings on the fine metal mask, particularly the openings at the edge, a number of dummy sub-pixels can be formed the edge of the pixel structure during preparing the pixel structure. These dummy sub-pixels are only intended to ensure the uniform size of the openings on the fine metal mask, not for light-emitting display.

In addition, it should be noted that, these drawings only schematically illustrate the arrangement of the plurality of sub-pixels, and the number of sub-pixels is not limited, and the number of sub-pixels can be set according to the requirements in actual products. In the meantime, the dashed-lines representing the pixel groups in the drawings are only intended to facilitate the viewing of the distribution principle of the sub-pixels, and the dashed-lines representing the pixel groups may not appear in the actual products. In addition, the size of the sub-pixel can be determined by the opening of the pixel definition layer, the size of the anode of the organic light-emitting element, or the size of the organic light-emitting layer, the size of the sub-pixel is not limited in the present invention.

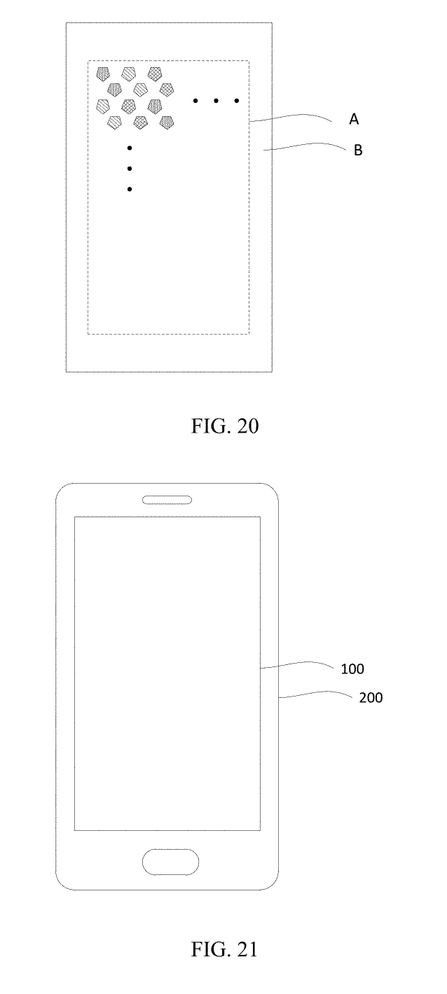

An embodiment of the present invention further provides a display panel, including any one of the pixel structures for organic light-emitting diodes provided in the above-mentioned embodiments. FIG. 20 is a display panel provided in an embodiment of the present invention. As shown in FIG. 20, the display panel includes a display area A and a non-display area B surrounding the display area. The pixel structure for organic light-emitting diodes is located in the display area A for displaying images.

An embodiment of the present invention further provides a display device, including the display panel provided in the above-mentioned embodiment. FIG. 21 is a display device provided in an embodiment of the present invention. As shown in FIG. 21, the display device includes a display panel 100 and a housing 200 for bearing the display panel. FIG. 21 shows a cell phone. The display device provided in embodiments of the present invention can also include tablet computers, virtual reality (VR) display device, on-board display device, television and the like, which have higher requirements on display effects.

It should be noted that above is merely intended to describe the preferred embodiments and the technical principles of the present invention. Those skilled in the art can understand that the present invention is not limited to these specific embodiments. Obviously, those skilled in the art can make various modifications, readjustments, combinations and substitutions, without departing from the protection scope of the invention. Therefore, although the present invention has been described in detail by way of the above embodiments, the present invention is not limited only to the above embodiments and more other equivalent embodiments can be included without departing from the concept of the present invention. The scope of the present invention is determined by the scope of the appended claims.

What is claimed is:

1. A pixel structure for organic light-emitting diodes, comprising three types of pixel groups arranged in an array, the three types of pixel groups being first pixel groups, second pixel groups and third pixel groups, respectively;
wherein each pixel group of each of the three types of pixel groups comprises two sub-pixels which are adjacent to each other and have a same color, the two sub-pixels are a first sub-pixel and a second sub-pixel respectively, and the sub-pixels in the pixel groups of different types have different colors;
any two of the pixel groups of a same type are neither adjacent to each other in a row direction of the array nor adjacent to each other in a column direction of the array;
the two sub-pixels of each of the pixel groups in a same row are arranged in a first direction or the two sub-pixels of each of the pixel groups in a same row are arranged in a second direction, and the second direction is perpendicular to the first direction; and
an included angle between the first direction and the row direction is α, 0°≤α≤90°.

2. The pixel structure for organic light-emitting diodes according to claim 1, wherein the first pixel groups, the second pixel groups and the third pixel groups are sequentially and cyclically arranged in the row direction.

3. The pixel structure for organic light-emitting diodes according to claim 2, wherein the two sub-pixels of each of the pixel groups in the same row are both arranged in the first direction.

4. The pixel structure for organic light-emitting diodes according to claim 3, wherein the first pixel groups, the second pixel groups and the third pixel groups are sequentially and cyclically arranged in the column direction.

5. The pixel structure for organic light-emitting diodes according to claim 4, wherein the column direction is the first direction.

6. The pixel structure for organic light-emitting diodes according to claim 2, wherein the two sub-pixels in each of the pixel groups in odd-numbered rows are arranged in the first direction, and the two sub-pixels in each of the pixel groups in even-numbered rows are arranged in the second direction.

7. The pixel structure for organic light-emitting diodes according to claim 6, wherein in a same column of the pixel groups, the pixel groups in the odd-numbered rows are the same type of pixel groups, the pixel groups in the even-numbered rows are the same type of pixel groups, and a type of the pixel groups in the odd-numbered rows is different from a type of the pixel groups in the even-numbered rows.

8. The pixel structure for organic light-emitting diodes according to claim 6, wherein in a same column of the pixel groups, the pixel groups in the odd-numbered rows and the pixel groups in the even-numbered rows are in a staggered arrangement, and in the column direction, geometric centers of the first sub-pixels are located on a same straight line, the second sub-pixels of the pixel groups in the odd-numbered rows are located on one side of the straight line, and the second sub-pixels of the pixel groups in the even-numbered rows are located on the other side of the straight line.

9. The pixel structure for organic light-emitting diodes according to claim 1, wherein in the pixel groups of a same row, in the row direction, geometric centers of the first sub-pixels are located on a same straight line and the first sub-pixels are arranged uniformly, and geometric centers of second sub-pixels are located on a same straight line and the second sub-pixels are arranged uniformly.

10. The pixel structure for organic light-emitting diodes according to claim 9, wherein a is 45°; and
in the pixel groups of a same row, an arrangement direction of two adjacent sub-pixels of two adjacent pixel groups is perpendicular to an arrangement direction of the two sub-pixels of each of the two adjacent pixel groups.

11. The pixel structure for organic light-emitting diodes according to claim 10, wherein in the pixel groups of a same column, geometric centers of the first sub-pixels are located on a same straight line, the first sub-pixels are uniformly arranged, geometric centers of the second sub-pixels of the pixel groups in odd-numbered rows are located on a same straight line, the second sub-pixels in the odd-numbered rows are uniformly arranged, geometric centers of the second sub-pixels of the pixel groups in even-numbered rows are located on a same straight line, the second sub-pixels in the even-numbered rows are uniformly arranged, a first interval is present between the straight line corresponding to the second sub-pixels of the pixel groups in the odd-numbered rows and the straight line corresponding to the first sub-pixels, and a second interval is present between the straight line corresponding to the second sub-pixels of the pixel groups in the even-numbered rows and the straight line corresponding to the first sub-pixels, wherein the first interval is equal to the second interval.

12. The pixel structure for organic light-emitting diodes according to claim 11, wherein the column direction is perpendicular to the row direction; in the pixel groups of the same row, a third interval is present between geometric centers of two adjacent first sub-pixels; and in the pixel groups of the same column, a fourth interval is present between geometric centers of two adjacent first sub-pixels, wherein the third interval is equal to the fourth interval.

13. The pixel structure for organic light-emitting diodes according to claim 1, wherein a is greater than 30° but less than 60°.

14. The pixel structure for organic light-emitting diodes according to claim 1, wherein the sub-pixels have a shape of square, two opposite sides of the square are parallel to the first direction, and the other two opposite sides of the square are perpendicular to the first direction.

15. The pixel structure for organic light-emitting diodes according to claim 1, wherein the sub-pixels have a shape of regular pentagon, regular hexagon or regular octagon.

16. The pixel structure for organic light-emitting diodes according to claim 1, wherein each of the two sub-pixels comprises an organic light-emitting element, and the organic light-emitting element comprises an anode, an organic light-emitting layer and a cathode, wherein the organic light-emitting layer is disposed between the anode and the cathode, and
the organic light-emitting layers of the two sub-pixels in each of the pixel groups are connected as an integral structure.

17. The pixel structure for organic light-emitting diodes according to claim 1, wherein the sub-pixels of the first pixel groups, the sub-pixels of the second pixel groups, and the sub-pixels of the third pixel groups have colors of red, green and blue, respectively.

18. A display panel, comprising a pixel structure for organic light-emitting diodes, wherein the pixel structure comprises: three types of pixel groups arranged in an array, the three types of pixel groups being first pixel groups, second pixel groups and third pixel groups, respectively;
wherein each pixel group of each of the three types of pixel groups comprises two sub-pixels which are adjacent to each other and have a same color, the two sub-pixels are a first sub-pixel and a second sub-pixel respectively, and the sub-pixels in the pixel groups of different types have different colors;
any two of the pixel groups of a same type are neither adjacent to each other in a row direction of the array nor adjacent to each other in a column direction of the array;
the two sub-pixels of each of the pixel groups in a same row are arranged in a first direction or the two sub-pixels of each of the pixel groups in a same row are arranged in a second direction, and the second direction is perpendicular to the first direction; and
an included angle between the first direction and the row direction is α, 0°≤α≤90°.

19. A display device, comprising a display panel, the display panel comprising a pixel structure for organic light-emitting diodes, wherein the pixel structure comprises: three types of pixel groups arranged in an array, the three types of pixel groups being first pixel groups, second pixel groups and third pixel groups, respectively;
wherein each pixel group of each of the three types of pixel groups comprises two sub-pixels which are adjacent to each other and have a same color, the two sub-pixels are a first sub-pixel and a second sub-pixel respectively, and the sub-pixels in the pixel groups of different types have different colors;
any two of the pixel groups of a same type are neither adjacent to each other in a row direction of the array nor adjacent to each other in a column direction of the array;
the two sub-pixels of each of the pixel groups in a same row are arranged in a first direction or the two sub-pixels of each of the pixel groups in a same row are arranged in a second direction, and the second direction is perpendicular to the first direction; and
an included angle between the first direction and the row direction is α, 0°≤α≤90°.
